(19) United States
(12) Patent Application Publication
(10) Pub. No.: US 2024/0224804 A1
(43) Pub. Date: Jul. 4, 2024

(54) THIN FILM TOUCH DEVICE AND MANUFACTURING METHOD THEREOF

(71) Applicant: TRANSDUCER STAR TECHNOLOGY CO., LTD., Hsinchu City (TW)

(72) Inventors: Jhih-Jhe WANG, Hsinchu City (TW); Sung-Cheng LO, Hsinchu City (TW); Chun-Kai CHAN, Hsinchu City (TW); Cheng-Syun LI, Hsinchu City (TW); Ming-Ching CHENG, Hsinchu City (TW); Yu-Chen CHEN, Hsinchu City (TW); Hsu-Hsiang CHENG, Hsinchu City (TW)

(21) Appl. No.: 18/092,672

(22) Filed: Jan. 3, 2023

(51) Int. Cl. H10N 30/30; G06F 3/01; G06F 3/041; H10N 30/00; H10N 30/05; H10N 30/50; H10N 30/857

(52) U.S. Cl. CPC H10N 30/302; G06F 3/016; G06F 3/0414; H10N 30/05; H10N 30/1071; H10N 30/503; H10N 30/857

(57) ABSTRACT

A sampling front-end for analog to digital converter is presented that shares a high speed N-bit ADC at front-end and interleaves the pipelined residue amplification with shared amplifier, which achieves high speed, low power and compact area with high density capacitive DAC structure.

### BACKGROUND OF THE INVENTION

### Field of the Invention

The present invention is directed to a thin film touch device. In particular, the present invention is directed to a piezoelectric thin film touch device with a feedback.

### Description of the Related Art

Presently, a touch device is widely applied in consumer electronics, such as a cell phone, a notebook, a smart TV, a touch panel, earphones, a watch and smart sensing clothing etc. However, a common touch device component, such as an electrostatic sensor component, a capacitive sensor component and a piezoresistive sensor component, may cause significant manufacturing cost and high power consumption.

In addition, in most conditions, when using a product with a touch device, a user should interact with a screen on the product by a visual sensation in combination with a touch operation. However, under certain situations, a user may not precisely perform a touch operation because the user's visual sensation may be restricted. For example, a user may be distracted to operate a touch screen while driving. For another example, a user may touch a button of earphones worn on his ears only by his hands without assistance of visual sensation. Under the situation described above, to operate a touch device with merely a visual sensation and a hand touch is not able to provide a good user experience.

### SUMMARY OF THE INVENTION

Thus, the present invention presents a touch thin film device and the manufacturing method thereof having lower manufacturing cost and power consumption, and bringing good user experiences to users.

The present invention presents a thin film touch device. The touch device includes a sensing unit, an actuation unit, a contact interface and an electrode. The sensing unit includes at least a first piezoelectric thin film. The actuation unit is electrically insulated with the sensing unit and the actuation unit includes a second piezoelectric thin film. The contact interface is arranged on the surface of the first piezoelectric thin film. The electrode is coupled to the sensing unit. Wherein, when performing a touch operation on the thin film touch device, the contact interface will deliver a pressure of touch into the sensing unit such that the first piezoelectric thin film deforms resulting in an induced charge variation, and wherein in response to sensing the charge variation, an actuation voltage is provided to the second piezoelectric thin film resulting in a converse piezoelectric feedback from the second piezoelectric thin film.

Preferably, the first piezoelectric thin film and/or the second piezoelectric thin film are composed of a piezoelectric polymer material, and wherein the piezoelectric polymer material includes a solid piezoelectric polymer membrane material, a liquid/solvent piezoelectric polymer solution material and a sol-gel piezoelectric polymer material.

Preferably, the electrode is an elastic metal thin film disposed on the first piezoelectric thin film.

Preferably, the actuation unit is electrically insulated with the sensing unit via a trench structure.

In an aspect, the trench structure includes a planar trench structure, which is formed according to the arrangement of the shape and position of the electrode.

Preferably, the contact interface includes a dimple/bump, used to optimally deliver the pressure/pushing force into the sensing unit.

In an aspect, the position and geometry of the dimple/bump are corresponding to the position and geometry of the first piezoelectric thin film when seeing at an angle of view from the top of the contact interface.

In an aspect, said geometry may be polygon, circle or any shape of geometry.

In an aspect, the electrode is provided on the surface of the dimple/bump.

Preferably, the outlines/contours of the first piezoelectric thin film and the second piezoelectric thin film may be polygon, circle or any shape of geometry when seeing at an angle of view from the top of the contact interface.

Preferably, the body of the first piezoelectric thin film and/or the second piezoelectric thin film may be porous structure or solid structure.

Preferably, there two first piezoelectric thin films, which may be applied in a double control switch.

Preferably, the first piezoelectric thin film and/or the second piezoelectric thin film may be made with an approach of multi thin film layer stack.

Preferably, a Dielectric-Barrier Discharge (DBD) polarization process is used to cause the first piezoelectric thin film and/or the second piezoelectric thin film to have the piezoelectric property.

The present invention further presents a method for manufacturing a thin film touch device, including: (a) depositing a piezoelectric material layer on a silicon wafer; (b) patterning the piezoelectric material layer with a resist to define a trench pattern, internal porous micro structures, and to define a sensing unit region and an actuation unit region by partitioning based on the trench pattern; (c) performing an etching process to form the defined pattern; (d) removing the resist and obtaining a piezoelectric material thin film by separating the etched piezoelectric material layer from the silicon wafer; (e) providing an electrode and polarizing the piezoelectric material thin film to obtain a piezoelectric thin film with the piezoelectric property; and (f) providing a contact interface on the piezoelectric thin film.

Preferably, the step of depositing the piezoelectric material layer on the silicon wafer further including: defining a micro structure pattern via a resist layer and stacking a multilayer of piezoelectric material to obtain the piezoelectric material layer with a multilayer stacked micro structure.

Preferably, the step of providing the electrode and polarizing the piezoelectric material thin film to obtain the piezoelectric thin film with the piezoelectric property including: after depositing a metal film over the surface of the piezoelectric material thin film to obtain the electrode, polarizing the piezoelectric material thin film with a process of Dielectric-Barrier Discharge.

Preferably, the step of providing the electrode and polarizing the piezoelectric material thin film to obtain the piezoelectric thin film with the piezoelectric property further including: heating the piezoelectric material thin film and depositing a metal film over the surface of the piezoelectric material thin film, and while the temperature of the piezoelectric material thin film is lowered to the room temperature, an elastic metal thin film electrode is obtained.

Preferably, the contact interface further includes a dimple/bump structure to optimally apply a pressure/pushing force into the piezoelectric thin film.

In an aspect, the steps of manufacturing the dimple/bump structure include: (a) defining shapes and positions of dimples/bumps on a metal, plastic, or silicon wafer mold; (b) molding a plastic or rubber material with the metal, plastic, or silicon wafer mold using injection molding, compress molding, or screen printing/spin-coating; and (c) separating the molded plastic or rubber material from the metal, plastic, or silicon wafer mold to obtain the contact interface with the dimple/bump structure.

In an aspect, the steps of manufacturing the dimple/bump structure further include: defining a region on which the metal film is to be deposited by using a shadow mask or resist (e.g., photoresist), and then depositing the metal film on a dimple/bump to form an electrode.

Hence, since the thin film touch device presented by the present invention includes the sensing unit and the actuation unit which are insulated with each other, a touch operation by a user and an actuation feedback to the user could be achieved at nearly the same time, such that while a user is operating the thin film touch device of the present invention, he is going through a good user experience. The thin film touch device presented by the invention senses a touch using piezoelectric effect and provides a feedback using converse piezoelectric effect such that the present invention presents a device with lower power consumption. In addition, the method for manufacturing a thin film touch device presented by the invention achieves the fabrication of a large scale of areas and further achieves the lowering of the manufacturing cost by using piezoelectric polymer in cooperation with MEMS (Micro-Electro-Mechanical System) fabrication process on a wafer.

### BRIEF DESCRIPTION OF THE DRAWINGS

Further features and aspects of the present invention will become apparent from the following detailed description of embodiments with reference to the attached drawings.

FIG. 1 shows a schematic sectional view of a thin film touch device 10 according to an embodiment of the invention;

FIGS. 2a-2d show a schematic top view of the thin film touch device 10 in FIG. 1 according to an embodiment of the invention;

FIG. 3 shows schematic cross section views, each of which is a manufacturing phase of a piezoelectric thin film of the thin film touch device 10 in FIG. 1 according to an embodiment of the invention;

FIG. 4 shows schematic cross section views, each of which is a manufacturing phase of a contact interface 15 with a dimple/bump structure 105 of the thin film touch device 10 in FIG. 1 according to an embodiment of the invention;

FIG. 5 shows a flowchart of a method 500 for manufacturing a thin film touch device according to an embodiment of the invention.

### DESCRIPTION OF THE EMBODIMENTS

For the following description, each embodiment may include the same element symbols, in which the same element symbols are referred to the same or the similar elements.

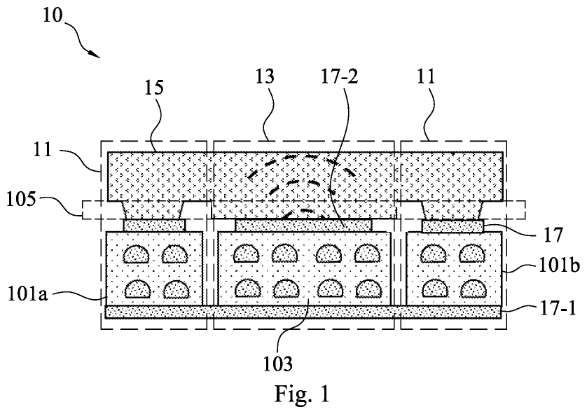

FIG. 1 shows a schematic sectional view of a thin film touch device 10 according to an embodiment of the invention. Referring to FIG. 1, a thin film touch device 10 includes a sensing unit 11, an actuation unit 13, a contact interface 15 and an electrode 17, wherein the sensing unit 11 includes at least one piezoelectric thin film 101a/101b, and the actuation unit 13 includes a piezoelectric thin film 103 electrically isolated/insulated with the piezoelectric thin film 101a/101b. The contact interface 15 is arranged on the sensing unit 11, and the electrode 17 is coupled to the sensing unit 11.

To be clear, said piezoelectric thin films 101a, 101b and 103 are thin films with the piezoelectric property. An object with “the piezoelectric property” means after polarizing a piezoelectric material (e.g., piezoelectric polymer) through a polarization process, this piezoelectric material become an object having a property of permanent built-in electric field. Generally, a “direct piezoelectric effect” occurs when a thin film with the piezoelectric property is pressed by an external force so as to deform such that two ends of the deformed thin film have positive charges and negative charges respectively. In addition, a “converse piezoelectric effect” occurs when applying an electric field to a thin film with the piezoelectric property so as to deform.

According to an embodiment of the invention, when a user operates the thin film touch device 10 by pressing the contact interface 15, the contact interface 15 will deliver a pressing force provided by the user to the sensing unit 11, such that the piezoelectric thin film 101a/101b of the sensing unit 11 deforms and further a charge variation happens because of the occurring of “direct piezoelectric effect”.

According to an embodiment of the invention, the charge variation is sensed by e.g., a controller (not shown) through the electrode 17 coupled to the sensing unit 11. In response to the charge variation generated because of pressing, the controller may provide an actuation voltage to the piezoelectric thin film 103, such that the piezoelectric thin film 103 deforms because of the occurring of “converse piezoelectric effect”, and further a feedback is generated. When the user receives the feedback, he will precisely perceive that the thin film touch device 10 is effectively pressed and this touch operation is achieved.

According to an embodiment of the invention, the piezoelectric thin film 103 generates a feedback (e.g., vibration) because of the deformation when receiving a voltage, and then delivers the feedback to the user via the contact interface 15. However, the present invention is not limited to it, according to a material of a piezoelectric thin film, when the piezoelectric thin film deforms, a resonance may occur so as to generate a sound, or heats, or force may occur. Thus, a user may hear a sound as a feedback or may feel heats, force or vibration as a feedback. Accordingly, any phenomenon occurs because of the deformation of the piezoelectric thin film could be so-called “feedback” in the present invention.

According to an embodiment of the invention, the piezoelectric thin films 101a, 101b and 103 may be composed of piezoelectric polymers. Piezoelectric polymers have properties of low rigidity, high stability, force impact resistance and anti-corrosion, which may be applied in a device required to be foldable, deformable, flexible, stretchable, such as wearable devices, like a smart watch, a smart wear and etc.

Generally, piezoelectric polymer materials include a solid piezoelectric polymer membrane or thin film material, a liquid/solvent piezoelectric polymer solution material and a sol-gel piezoelectric polymer material. The piezoelectric polymer membrane material/thin film may include e.g., PVDF, PVDF-TrFE and the copolymer thereof. The liquid/solvent piezoelectric polymer solution material may include e.g., a solution derived by modulation with PVDF and PVDF-TrFE. The sol-gel piezoelectric polymer material may include e.g., a sol-gel produced with PVDF-TrFE and the copolymer thereof, Nylon-11, PLLA, etc.

According to an embodiment of the invention, the electrode 17 may be disposed over the piezoelectric thin film 101a/101b. A sensing device (e.g., a controller) may sense a charge variation resulted from the pressing of the piezoelectric thin film 101a/101b via the electrode 17.

According to an embodiment of the invention, a feedback of converse piezoelectric effect may be generated by applying an actuation voltage to the piezoelectric thin film 103 through a metal thin film 17-1 and/or a metal thin film 17-2. It is noteworthy that although the sensing unit 11 and the actuation unit 13 are required to be electrically isolated such that a feedback of converse piezoelectric effect could be provided while sensing a charge variation of direct piezoelectric effect, the electrode 17 and the metal thin film 17-2 which are disconnected from each other could be used to sense a charge variation and to receive an actuation voltage respectively. Thus, in the embodiment of FIG. 1, the metal thin film 17-1 is not necessarily to be disconnected for electrically insulating the sensing unit 11 with the actuation unit 13.

According to an aspect of the embodiment, the electrode 17 (or the metal thin films 17-1, 17-2) may be an elastic metal thin film to coordinate with e.g., a wearable device that is required to be bent in use. An elastic metal thin film could be made as the following method: firstly, heating a thin film sample; secondly, depositing a metal on the surface of the heated thin film sample; and a flexibly elastic metal thin film could be obtained after being cooled to the room temperature. In addition, a common metal material used for the elastic metal thin film includes: Au, Ti, Cu, Cr, Al, Ni, Pt, etc.

According to an embodiment of the invention, since the sensing unit 11 and the actuation unit 13 are electrically insulated to each other, the actuation unit 13 could deliver a feedback (e.g., a vibration) to a user while the sensing unit 11 is sensing a touch. Because the sensing unit 11 is isolated with the actuation unit 13, sensing a touch and delivering a feedback do not conflict with each other and could be performed synchronously.

According to an embodiment of the invention, the sensing unit 11 may be electrically isolated with the actuation unit 13 by separating the piezoelectric thin film 101a/101b from the piezoelectric thin film 103 via a trench structure. In an aspect of the embodiment, the trench structure could be a planar trench structure formed based on the shapes and positions of the electrode 17 and the metal thin film 17-2.

According to an embodiment of the invention, the contact interface 15 arranged on the sensing unit 11 further includes a dimple/bump structure 105. Dimples/bumps in the dimple/bump structure 105 may assist a user to optimally deliver a pressure/pushing force generated when performing a touch operation into the piezoelectric thin film 101a/101b of the sensing unit 11. That is to say, compared to a thin film touch device 10 without any dimple/bump structure, a user may operate a thin film touch device 10 having a contact interface 15 with a dimple/bump structure 105 by using less force. According to an aspect of the embodiment, a contact interface 15 having dimples/bumps may be provided over the actuation unit 13 to assist delivering a feedback (e.g., a vibration) to a user for perceiving.

According to an embodiment of the invention, the sensing unit 11 may include a piezoelectric thin film 101a or 101b, which is electrically isolated/insulated with the piezoelectric thin film 103 and coupled to the electrode 17. Herein, a piezoelectric thin film may mean one or more piezoelectric thin films corresponding to one function e.g., when the thin film touch device 10 is applied in a simply input device, such as a thin film keyboard or switch with a vibration feedback.

According to an embodiment of the invention, the sensing unit 11 may include two piezoelectric thin films 101a and 101b, which are coupled to the electrode 17, respectively. A thin film touch device 10 with two piezoelectric thin films 101a and 101b may be applied in e.g., a double control switch. For example, under the case of applying in e.g., a double control switch with a function of adjusting volume, when sensing a charge variation at the end of the piezoelectric thin films 101a, in addition to providing an actuation voltage for generating a feedback, a controller may execute e.g., a function of turning a volume of a speaker down. In contrast, when sensing a charge variation at the end of the piezoelectric thin films 101b, the controller may execute e.g., a function of turning a volume of a speaker up. However, the present invention is not limited to it, more piezoelectric thin films may be provided in the sensing unit 11 for more functions, such as a triple control switch, a quadruple control switch.

It is noteworthy that, although not shown, the path of providing an actuation voltage to the actuation unit 13 is implemented via a circuit layout technique. The circuit layout technique for implementing the actuation voltage path is a known knowledge in the present technical field and thus will not be explained in detail herein again.

According to an embodiment of the invention, the controller may be e.g., a microcontroller, a Center Processing Unit (CPU), a Digital Signal Processor (DSP), a Field Programmable Gate Array (FPGA), etc. However, the present invention is not limited to the description above, all the devices which are able to detect the charge variation of the sensing unit and to provide an actuation voltage to the actuation unit could be the controller described in the present invention.

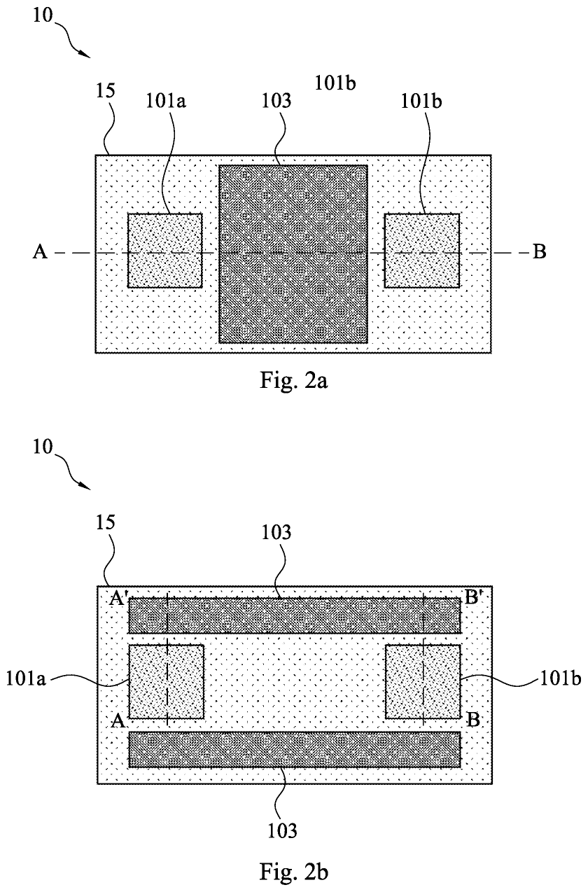

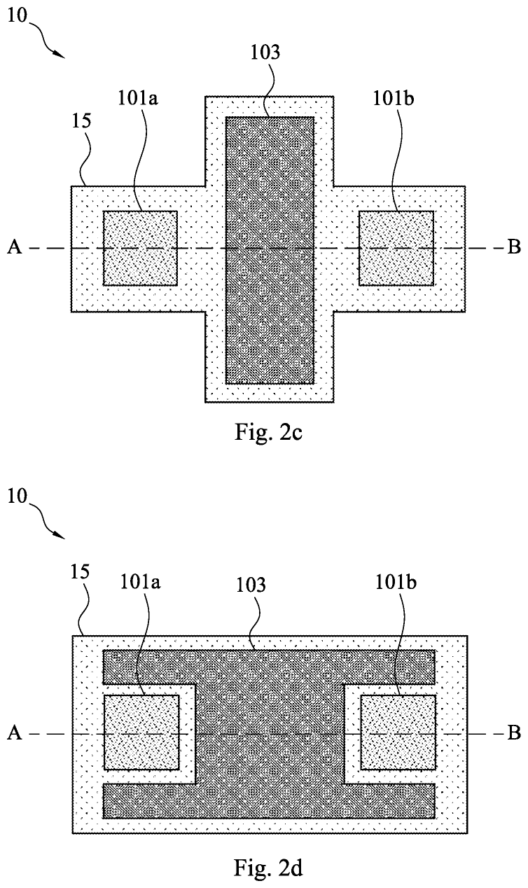

FIGS. 2a-2d show a schematic top view of the thin film touch device 10 in FIG. 1 according to an embodiment of the invention. As shown in FIGS. 2A-2d, when seeing at a top view point over the contact interface 15, FIGS. 2a, 2c and 2d show a rectangle thin film touch device 10 and FIG. 2b shows a polygon thin film touch device 10. In addition, piezoelectric thin films 101a, 101b and 103 may also be rectangle, polygon, circle or any other shapes. However, the present invention is not limited to this, as long as the feature that at least one piezoelectric thin film 101a/101b in the sensing unit is insulated with a piezoelectric thin film 103 in the actuation unit via a trench is met, all the components included in the thin film touch device 10 presented in the invention, including the piezoelectric thin films, 101a, 101b and 103, the contact interface 15, the electrode 17, the metal thin film 17-1 and 17-2 could be any shapes, such as rectangle, polygon or circle. For example, cross sections along a dash line AB of FIGS. 2a, 2c and 2d are corresponding to a schematic sectional view of the thin film touch device 10 in FIG. 1. As another example shown in FIG. 2b, a cross section along a dash line AA′ in FIG. 2b is corresponding to a schematic sectional view of FIG. 1 ranged from the piezoelectric thin film 101a to the left side of the piezoelectric thin film 103, and a cross section along a dash line BB′ in FIG. 2b is corresponding to a schematic sectional view of FIG. 1 ranged from the right side of the piezoelectric thin film 103 to the piezoelectric thin film 101b.

According to an embodiment of the invention, since the dimple/bump structure 105 is used to optimally deliver the pressure pressed by a user, the position and geometry of the dimples/bumps of the dimple/bump structure 105 should be corresponding to the position and geometry of the piezoelectric thin films 101a, 101b and 103 when seeing at a top view point over the contact interface 15.

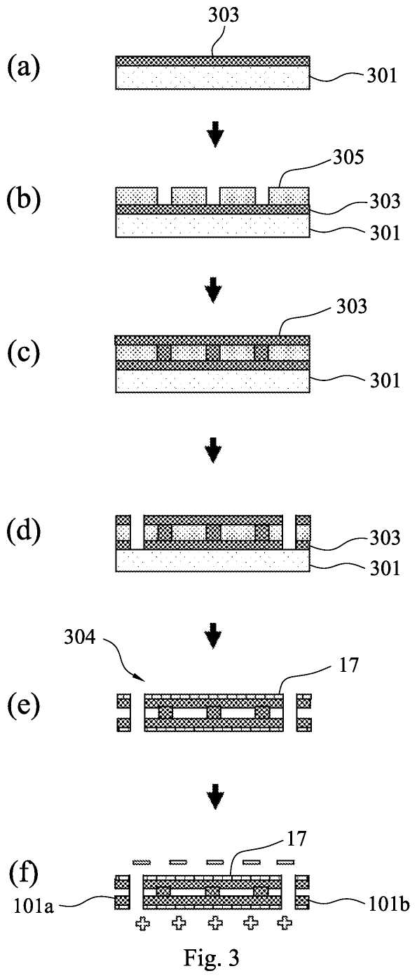

FIG. 3 shows schematic cross section views, each of which is a manufacturing phase of a piezoelectric thin film of the thin film touch device 10 in FIG. 1 according to an embodiment of the invention. Referring to FIG. 3, firstly during phase (a), a piezoelectric material 303 is deposited over a silicon wafer 301 and the piezoelectric material 303 may be e.g., a material of piezoelectric polymer. Since the present invention provides the silicon wafer 301 under a semiconductor process, the deposition of a large scale of areas over the silicon wafer 301 is beneficial for saving cost.

During phase (b), a microstructure pattern is defined over the piezoelectric material with a resist 305 (e.g., a photoresist or shadow mask layer). During phase (c), a multilayer material stack is achieved by depositing a further layer of piezoelectric polymer material 303. Please note that the phases (b) and (c) will be proceeded only if a multilayer material stack is required. In addition, to repeat phases (b) and (c), a stack with more layers of the piezoelectric polymer material 303 could be further achieved.

During phase (d), a trench pattern is defined with a resist 305 (e.g., a photoresist or shadow mask) for partitioning into a sensing unit and an actuation unit, and an etching process (e.g., a plasma etching) is performed to form the defined trench pattern (e.g., a planar trench structure). During phase (d), after the trench is formed, the resist 305 (e.g., a photoresist or shadow mask) may be removed.

During phase (e), the piezoelectric material 303 with a patterned trench is separated from the silicon wafer, and metal thin films are deposited under and over the patterned piezoelectric material to form an electrode 17, thereby a piezoelectric material thin film 304 is obtained. According to an embodiment of the invention, before depositing the metal thin films, the piezoelectric material 303 with a patterned trench could be heated in advance, and then after the deposition of the metal films is completed and the temperature is lowered to the room temperature, a piezoelectric material thin film 304 with an elastic metal thin film electrode is obtained.

During phase (f), a polarization process is performed for polarizing the piezoelectric material thin film 304 separated from the silicon wafer. The polarization process may be a Dielectric-Barrier Discharge polarization process. Such that, the piezoelectric material thin film 304 has the piezoelectric property with a permanent built-in electric field, and further the piezoelectric thin film 101a/101b in the sensing unit and the piezoelectric thin film 103 in the actuation unit are achieved.

Please note that, during phase (d), a trench structure is formed (e.g., a planar trench structure). Then, during phase (e), a metal thin film is deposited to provide the electrode 17. However, it is also possible to form the electrode 17 with a trench structure by performing a lithography, etching process on the metal thin film after the metal thin film is deposited.

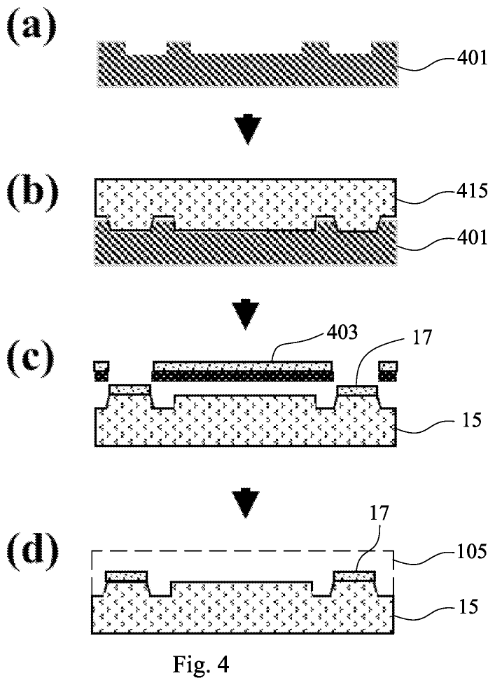

FIG. 4 shows schematic cross section views, each of which is a manufacturing phase of a contact interface 15 with a dimple/bump structure 105 of the thin film touch device 10 in FIG. 1 according to an embodiment of the invention. Referring to FIG. 4, during phase (a), shapes and positions of dimples/bumps are designed and defined on a metal, plastic, or silicon wafer mold 401. During phase (b), a plastic or rubber material 415 is molded with the metal, plastic, or silicon wafer mold 401 using injection molding, compress molding, or screen printing/spin-coating. Then, the molded plastic or rubber material 415 is separated from the metal, plastic, or silicon wafer mold 401 so as to obtain the contact interface 15 with a dimple/bump structure.

According to an embodiment of the invention, in addition to being provided on the piezoelectric thin film, the electrode 17 could also be provided on the dimples/bumps of the dimple/bump structure 105 of the contact interface 15. The manufacturing method thereof are as described in the phases (c) and (d) in FIG. 4 below. During phase (c), after separated from the metal, plastic, or silicon wafer mold, regions over the dimples/bumps of the contact interface 15 where metal thin films are to be deposited are defined with a shadow mask or resist 403, and then the metal thin films are deposited on the surfaces of the dimples/bumps of the dimple/bump structure according to the defined region. During phase (d), after the metal thin films are deposited, the shadow mask or resist 403 is removed so as to obtain a contact interface 15 with electrodes 17 provided on the dimples/bumps.

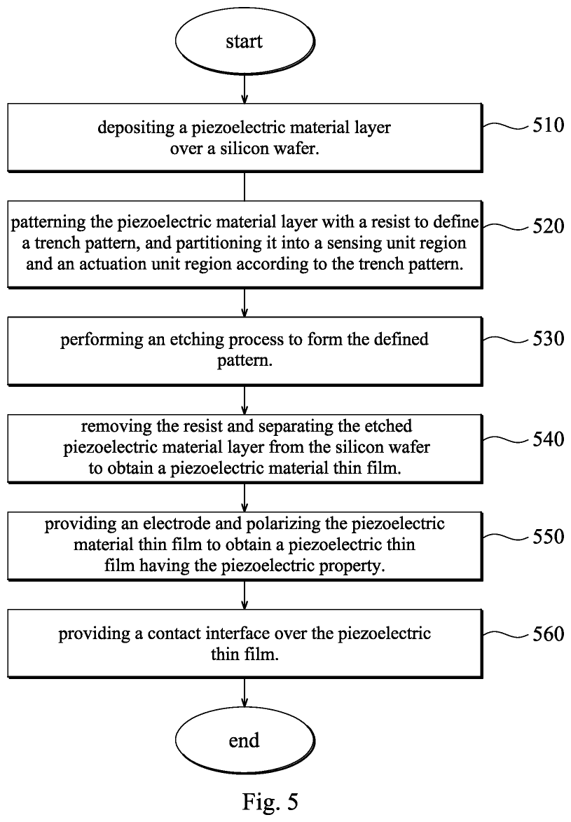

FIG. 5 shows a flowchart of a method 500 for manufacturing a thin film touch device with a feedback according to an embodiment of the invention. Referring to FIG. 5, according to an embodiment of the invention, a method for manufacturing a thin film touch device could be obtained according to the method of manufacturing a piezoelectric thin film as described in FIG. 3 in combination with the method of manufacturing a contact interface as described in FIG. 4.

The method 500 includes a step 510: depositing a piezoelectric material layer over a silicon wafer. Herein, the piezoelectric material layer is preferably a multilayer piezoelectric polymer thin film. Since the silicon wafer is introduced, manufacturing with a large scale of areas is achieved.

According to an embodiment of the invention, to achieve a multilayer piezoelectric polymer thin film, step 510 further includes the following sub-step: defining a micro-structure pattern with a resist and stacking the multilayer piezoelectric material to obtain a piezoelectric material layer of stacked multilayer porous micro-structure.

According to an embodiment of step 510, the resist may be e.g., a photoresist. However, the present invention is not limited to it, any resist that could be used to define a micro-structure is applicable. It is preferable to use a multilayer piezoelectric polymer material as the multilayer piezoelectric material for stacking.

The method 500 includes a step 520: patterning the piezoelectric material layer with a resist to define a trench pattern, porous micro-structure and partitioning it into a sensing unit region and an actuation unit region according to the trench pattern. The resist may be e.g., a photoresist. However, the present invention is not limited to it, other example may include a hard mask or screen mask/shadow mask (e.g., Silicon Nitride or Stainless Steel plate).

The Method 500 includes a step 530: performing an etching process to form the defined pattern. In this step, a trench could be made with an etching process, such as a plasma etching process, to form the sensing unit region and the actuation unit region defined at the step 520. The etching process is not limited to the plasma etching process. For example, other methods with physical or chemical type properties such as wet etching or dry etching processes may be also applicable.

The method 500 includes a step 540: removing the resist (e.g., a photoresist) and separating the etched piezoelectric material layer from the silicon wafer to obtain a piezoelectric material thin film. In this step, after achieving the sensing unit region and the actuation unit region on a large scale area of piezoelectric polymer material thin film, then it could be taken out from the wafer.

The method 500 includes a step 550: providing an electrode and polarizing the piezoelectric material thin film to obtain a piezoelectric thin film having the piezoelectric property. An approach to provide an electrode includes: depositing a metal thin film over and under the piezoelectric material thin film that was taken out from the wafer. After providing the electrode, polarizing the piezoelectric material thin film by using e.g., a Dielectric-Barrier Discharge process.

When using said “Dielectric-Barrier Discharge process”, a piezoelectric material will be placed within a pair of parallel plates with insulating layers. Since merely a high-voltage electric field passes through the pair of parallel plates and breakdown currents are shielded, the molecules of piezoelectric materials under the high-voltage electric field which are generated the electric dipole moment such that the piezoelectric material has the piezoelectric property because of having a built-in electric field. It is a known knowledge in this field to use a Dielectric-Barrier Discharge process for polarizing and thus will not be illustrated in detail herein again.

According to an embodiment of step 550, the piezoelectric material thin film taken out from the wafer may be pre-heated/heated in advance and then depositing metal films over and under the surfaces of the heated piezoelectric material thin film. Later, when the temperature of the piezoelectric material thin film is lowered to the room temperature, a piezoelectric thin film with an elastic metal thin-film electrode is obtained.

The method 500 includes a step 560: providing a contact interface over the piezoelectric thin film. According to an embodiment of step 560, a contact interface may include a dimple/bump structure to optimally deliver and apply a pressure generated when a user performs a touch/contact operation to the piezoelectric thin film.

According to an embodiment of the invention, the method for manufacturing the dimple/bump structure further include the following sub-steps: (a) defining shapes and positions of dimples/bumps on a metal, plastic, or silicon wafer mold; (b) molding a plastic or rubber material with the metal, plastic, or silicon wafer mold using injection molding, compress molding, or screen printing/spin-coating; and (c) separating the molded plastic or rubber material from the metal, plastic, or silicon wafer mold to obtain the contact interface with the dimple/bump structure.

It is noteworthy that since the piezoelectric thin films in the sensing unit may be placed at any positions and may be any shapes according to user's design/requirement, the positions and shapes of the dimples/bumps in the dimple/bump structure may be required to be corresponding to those of the piezoelectric thin films in the sensing unit so as to optimally deliver a pressure/force from a user's touch operation to the piezoelectric thin films in the sensing unit. Therefore, it may be required to define the positions and shapes of the dimples/bumps with a mold in advance.

According to an embodiment of the step 560, the step of manufacturing the dimple/bump structure further include: defining regions where metal films are to be deposited on the dimples/bumps with a shadow mask or resist, and then depositing the metal films on the dimples/bumps to form an electrode. It is noteworthy that while a user is performing a touch operation, the dimples/bumps in the dimple/bump structure is in contact with the piezoelectric thin films. Hence, in addition to providing the electrode over the piezoelectric thin films, the electrode may also be provided over the dimples/bumps so as to sensing a charge variation via the electrode over the dimples/bumps when performing a touch operation. Alternatively, according to a further embodiment, both the piezoelectric thin films and the dimples/bumps are provided with electrodes.

Although specific embodiments of the invention have been illustrated herein, it will be appreciated by those of ordinary skill in the art that specifics for the embodiments above could be amended and modified without departing from the scope of the present invention. Therefore, it is intended that this invention be limited only by the claims and the equivalents thereof.

What is claimed is:

1. A thin film touch device, comprising:
a sensing unit, comprising at least one first piezoelectric thin film;
an actuation unit, electrically insulated with the sensing unit, the actuation unit comprising a second piezoelectric thin film;
a contact interface, arranged on the sensing unit; and
an electrode, coupled to the sensing unit and the actuation unit;
wherein when performing a touch operation on the thin film touch device, the contact interface will deliver a pressure of touch into the sensing unit such that the at least one first piezoelectric thin film deforms resulting in inductively a charge variation, and wherein in response to sensing the charge variation, an actuation voltage is provided to the second piezoelectric thin film resulting in a converse piezoelectric feedback from the second piezoelectric thin film.

2. The thin film touch device as claimed in claim 1, wherein the at least one first piezoelectric thin film and/or the second piezoelectric thin film are composed of a piezoelectric polymer material, and wherein the piezoelectric polymer material comprises a solid piezoelectric polymer membrane/thin film material, a liquid/solvent piezoelectric polymer solution material and a sol-gel piezoelectric polymer material.

3. The thin film touch device as claimed in claim 1, wherein the electrode is an elastic metal thin film disposed on the at least one first piezoelectric thin film and/or the second piezoelectric thin film.

4. The thin film touch device as claimed in claim 1, wherein the actuation unit is electrically insulated with the sensing unit via a trench structure.

5. The thin film touch device as claimed in claim 4, wherein the trench structure comprises a planar trench structure, which is formed according to the arrangement of the shape and position of the electrode.

6. The thin film touch device as claimed in claim 1, wherein the contact interface comprises a dimple/bump, used to optimally deliver the pressure into the sensing unit.

7. The thin film touch device as claimed in claim 6, wherein the position and geometry of the dimple/bump are corresponding to the position and geometry of the first piezoelectric thin film when seeing at an angle of view from the top of the contact interface.

8. The thin film touch device as claimed in claim 7, wherein the geometry is polygon, circle or any shape of geometry.

9. The thin film touch device as claimed in claim 6, wherein the electrode is provided on the surface of the dimple/bump.

10. The thin film touch device as claimed in claim 1, wherein the outlines/contours of the first piezoelectric thin film and the second piezoelectric thin film are polygon, circle or any shape of geometry when seeing at an angle of view from the top of the contact interface.

11. The thin film touch device as claimed in claim 1, wherein the body of the at least one first piezoelectric thin film and/or the second piezoelectric thin film is porous structure or solid structure.

12. The thin film touch device as claimed in claim 1, wherein the at least one first piezoelectric thin film comprises one/or two or above piezoelectric thin films, which may be applied in a double control switch.

13. The thin film touch device as claimed in claim 1, wherein the at least one first piezoelectric thin film and/or the second piezoelectric thin film is made with an approach of multi thin film layer stack.

14. The thin film touch device as claimed in claim 1, wherein a Dielectric-Barrier Discharge (DBD) polarization process is used to cause the at least one first piezoelectric thin film and/or the second piezoelectric thin film to have the piezoelectric property.

15. A method for manufacturing a thin film touch device, comprising:
(a) depositing a piezoelectric material layer on a silicon wafer;
(b) patterning the piezoelectric material layer with a resist to define a trench pattern, internal porous micro structures, and to define a sensing unit region and an actuation unit region by partitioning based on the trench pattern;
(c) performing an etching process to form the defined pattern;
(d) removing the resist and obtaining a piezoelectric material thin film by separating the etched piezoelectric material layer from the wafer;
(e) providing an electrode and polarizing the piezoelectric material thin film to obtain a piezoelectric thin film with the piezoelectric property; and
(f) providing a contact interface on the piezoelectric thin film.

16. The method as claimed in claim 15, wherein the step of depositing the piezoelectric material layer on the silicon wafer further comprising:
defining a micro structure pattern via a resist layer and stacking a multilayer of piezoelectric material to obtain a piezoelectric material layer with a multilayer stacked porous micro structure.

17. The method as claimed in claim 15, the step of providing the electrode and polarizing the piezoelectric material thin film to obtain the piezoelectric thin film with the piezoelectric property comprising:
after depositing a metal film over the surface of the piezoelectric material thin film to obtain the electrode, polarizing the piezoelectric material thin film with a process of Dielectric-Barrier Discharge.

18. The method as claimed in claim 15, wherein the step of providing the electrode and polarizing the piezoelectric material thin film to obtain the piezoelectric thin film with the piezoelectric property further comprising:
heating the piezoelectric material thin film and depositing a metal film over the surface of the piezoelectric material thin film, and while the temperature of the piezoelectric material thin film is lowered to the room temperature, an elastic metal thin-film electrode is obtained.

19. The method as claimed in claim 15, wherein the contact interface further comprises a dimple/bump structure to optimally impose a pressure/or force into the piezoelectric thin film.

20. The method as claimed in claim 19, wherein the steps of manufacturing the dimple/bump structure comprise:
(a) defining shapes and positions of dimples/bumps on a metal, plastic, or silicon wafer mold;
(b) molding a plastic or rubber material with the metal, plastic, or silicon wafer mold using injection molding, compress molding, or screen printing/spin-coating; and
(c) separating the molded plastic or rubber material from the metal, plastic, or silicon wafer mold to obtain the contact interface with the dimple/bump structure.

21. The method as claimed in claim 20, wherein the steps of manufacturing the dimple/bump structure further comprise:
defining a region on which the metal film is to be deposited by using a shadow mask or resist and then depositing the metal film over a dimple/bump to form an electrode.
